(19) United States
(12) Patent Application Publication
(10) Pub. No.: US 2002/0000593 A1
(43) Pub. Date: Jan. 3, 2002

(54) Semiconductor device and method of manufacturing the same

(76) Inventors: Akira Nishiyama, Yokohama-shi (JP); Masato Koyama, Miura-gun (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 09/891,129

(22) Filed: Jun. 26, 2001

(30) Foreign Application Priority Data
Jun. 27, 2000 (JP) 2000-193215

(51) Int. Cl. H01L 27/108; H01L 29/76; H01L 29/94; H01L 31/119

(52) U.S. Cl. 257/296

(57) ABSTRACT

Disclosed is a semiconductor device comprising a semiconductor substrate and a circuit element using an insulating film formed on the semiconductor substrate. The insulating film contains a silicon compound containing at least one element selected from the group consisting of an oxygen and a nitrogen, and a metal compound containing a metal other than silicon and at least one element selected from the group consisting of an oxygen and a nitrogen. Nano-crystals are formed in the insulating film. The size of the nano-crystal is small enough to permit observation of a polycrystalline ring as a diffraction image when an electron beam having a beam diameter of the nanometer order is incident in parallel to the insulating film surface.

### CROSS-REFERENCE TO RELATED APPLICATIONS

This application is based upon and claims the benefit of priority from the prior Japanese Patent Application No. 2000-193215, filed Jun. 27, 2000, the entire contents of which are incorporated herein by reference.

### BACKGROUND OF THE INVENTION

The present invention relates to a semiconductor device using a highly dielectric thin film, i.e., a thin film having a high dielectric constant, as an insulating film used as, for example, a gate insulating film, particularly, to a semiconductor device in which nano-crystals are precipitated in a highly dielectric thin film and a method of manufacturing the same.

Miniaturization of the MOS transistor proceeds rapidly nowadays and has arrived at the stage where the gate length of 0.1 μm is near at hand. The progress of miniaturization is based on the situation that it leads to a high element operating speed and also to low power consumption. In addition, miniaturization itself permits diminishing the area occupied by the element so as to make it possible to mount more elements on the same chip area. It is considered reasonable to understand that miniaturization is pursued because it also satisfies allowing the LSI itself to perform many functions.

However, it is expected that the pursuit of miniaturization will reach a deadlock before the gate length is decreased to 0.1 μm because the reduction in the thickness of the gate insulating film is limited.

It was customary to use SiO₂ for forming the gate insulating film positioned below the gate electrode because SiO₂ satisfies the two characteristics indispensable for the operation of the element: the SiO₂ film only bears a minute stationary charge, and, the interfacial level is not formed between the SiO₂ film and the Si layer of the channel portion. Also, SiO₂ is advantageous in that a thin SiO₂ film can be formed easily with good controllability. Because SiO₂ has a low relative dielectric constant of 3.9, a gate insulating film made of SiO₂ and having a thickness not less than 3 nm is required, to satisfy the performance of next generation transistors with a gate length of 0.1 μm. However, it is expected that, in the gate insulating film having a thickness of this level, an increase in the leakage current between the gate and the substrate, which is caused by the direct tunneling phenomenon of the carrier, will pose a problem. The trade off relationship is an unavoidable problem if SiO₂ is used for forming the gate insulating film.

Under the circumstances, vigorous studies are also being made in an attempt to avoid the tunneling problem noted above by using a material having a relative dielectric constant higher than that of SiO₂. Such studies are being made on films of metal oxides such as Ta₂O₅ and TiO₂. Since Ta₂O₅ and TiO₂ have a relative dielectric constant of about 20 and about 90, respectively, in contrast to 3.9 for SiO₂ as noted above, it is possible to form the films of Ta₂O₅ and TiO₂ that are about 5 times and about 20 times as thick as the SiO₂ film, to obtain the same gate capacitance and, thus, Ta₂O₅ and TiO₂ are considered to be materials effective in suppressing the tunneling problem.

However, in the metal oxide/Si structure formed by any of the conventional methods, it is unavoidable for the polycrystal of the metal oxide to be formed through the heat treating step carried out at temperatures higher than 800° C. for forming the transistor. The problems inherent in the conventional refractory metal oxide thin film thus formed will now be described with reference to FIG. 1. In FIG. 1, reference numeral 90 denotes a silicon substrate, reference numeral 92 denotes a TiO₂ film, which is a highly dielectric metal oxide thin film, reference numeral 94 denotes a gate electrode, and reference numeral 95 denotes a grain boundary.

A first problem inherent in the structure shown in FIG. 1 is that an electric current is likely to flow through the grain boundary 95 so as to increase the leakage current between the gate and the substrate. A difficulty is considered to be brought about by the fact that the metal-oxygen bond is incomplete in the grain boundary region, compared with the grain region. Also, it is said that, even in the boundary in which a complete bond is once obtained, fatigue tends to occur if an electric current is allowed to flow through the boundary. In other words, an SILC (Stress Induced Leakage Current) tends to flow, which increases the leakage current.

A second problem arising from the generation of the grain boundary in a thin film of a refractory metal is that polycrystalline grains are oriented at random, which renders the effective relative dielectric constant nonuniform. The difficulty is caused by the fact that the microcrystalline highly dielectric material has an anisotropy in its relative dielectric constant εᵣ. For example, TiO₂ exhibits a relative dielectric constant εᵣ of 89 where an electrode is formed in parallel to the c-axis and exhibits a relative dielectric constant εᵣ of 170 where an electrode is formed in a direction perpendicular to the c-axis.

It should also be noted that, where a TiO₂ layer is formed by, in general, a sputtering method or a CVD method and, then, subjected to a heat treatment at temperatures not lower than 800° C., the grain size within the thin film of the refractory metal falls within a range of between 10 nm and 50 nm. It follows that, in the case of forming a MOS transistor having a gate length Lg of, for example, 30 nm, the threshold voltage Vₜₕ and the current driving force Iₜ are rendered nonuniform as shown in FIGS. 2A and 2B depending on the portion of the TiO₂ layer, which is oriented at random, on which the gate electrode is formed. This is a major defect in forming a MOS transistor in an LSI, making it impossible to form a circuit of good characteristics.

### BRIEF SUMMARY OF THE INVENTION

As described above, the problems in using a metal oxide for forming a gate insulating film can be summarized as follows.

(1) The leakage current between the gate electrode and the substrate is increased by the leakage current in the grain boundary.

(2) The increase in the leakage current between the gate electrode and the substrate that is induced by the application of the current stress (SILC) is prominent.

(3) The threshold value and the driving force of a very small MOS transistor, which is smaller than 50 nm, are rendered nonuniform, which makes it difficult to design an LSI.

The present invention, which has been achieved in view of the situation described above, is intended to provide a semiconductor device, which permits suppressing the leakage current derived from the grain boundary, permits suppressing the nonuniformity in the threshold value and the driving force, and also permits improving the characteristics of a MOS transistor, etc. and a method of manufacturing the particular semiconductor device.

The present invention is also intended to provide a semiconductor device, which permits suppressing the leakage current derived from the crystal grain boundary, eliminates trapped charges within the film so as to suppress the nonuniformity in the threshold value and the driving force, and is effective in improving the characteristics of a MOS transistor, etc. and a method of manufacturing the particular semiconductor device.

According to one aspect of the present invention, there is provided a semiconductor device comprising:

a semiconductor substrate, and

a circuit element using an insulating film formed on the semiconductor substrate,

the insulating film containing a silicon compound containing at least one element selected from the group consisting of an oxygen and a nitrogen, and a metal compound containing a metal other than silicon and at least one element selected from the group consisting of an oxygen and a nitrogen, nano-crystals being formed in the insulating film, the size of the nano-crystal being small enough to permit observation of a polycrystalline ring as a diffraction image when an electron beam having a beam diameter of the nanometer order is incident in parallel to the insulating film surface.

Further, according to another aspect of the present invention, there is provided a method of manufacturing a semiconductor device of the present invention, comprising:

forming an insulating film containing a silicon compound containing at least one element selected from the group consisting of an oxygen and a nitrogen, and a metal compound containing a metal other than silicon and at least one element selected from the group consisting of an oxygen and a nitrogen, on a semiconductor substrate under temperatures at which crystallization does not take place; and

applying a heat treatment to precipitate a nano-crystalline metal oxide within the mixed film.

Further, according to another aspect of the present invention, there is provided a method of manufacturing a semiconductor device of the present invention, comprising:

forming insulating film being a mixed film including a silicon compound containing at least one element selected from the group consisting of an oxygen and a nitrogen, and a metal compound containing a metal other than silicon and at least one element selected from the group consisting of an oxygen and a nitrogen on a semiconductor substrate under temperatures at which crystallization does not take place; and

applying a heat treatment to precipitate a nano-crystalline metal oxide within the mixed film.

### BRIEF DESCRIPTION OF THE SEVERAL VIEWS OF THE DRAWING

FIG. 1 is a cross sectional view for explaining the problems inherent in the prior art;

FIGS. 2A and 2B are graphs for explaining the problems inherent in the prior art;

FIG. 3 is a cross sectional view showing the basic structure of a semiconductor device according to one embodiment of the present invention;

FIGS. 4A to 4E are cross sectional views collectively showing as an example the manufacturing process of a semiconductor device for Example 1 of the present invention;

FIG. 5 is a graph showing that the leakage current is suppressed in accordance with an increase in the silicon content of the gate insulating film;

FIG. 6 is a graph showing an estimated nonuniformity of the threshold value and the effect of suppressing the nonuniformity produced by the application of one embodiment of the present invention;

FIG. 7 is a graph showing the relationship between the silicon content of the gate insulating film and the relative dielectric constant;

FIGS. 8A to 8E are cross sectional views collectively showing the manufacturing process of a semiconductor device for Example 3 of the present invention;

FIG. 9 is a cross sectional view showing the construction of an element according to a modification of Example 3 of the present invention;

FIGS. 10A to 10D are cross sectional views collectively showing the manufacturing process of a semiconductor device for Example 4 of the present invention;

FIG. 11 is a cross sectional view schematically showing the nano-crystals within the mixed film;

FIG. 12 is a drawing schematically showing the levels in the thickness direction under the state shown in FIG. 11;

FIGS. 13A to 13C are cross sectional views collectively showing the basic structure of the semiconductor device according to other embodiment of the present invention;

FIGS. 14A and 14B are graphs each showing the dependence of the C-V (capacitance-gate voltage) characteristics on the thickness of the film; and

FIGS. 15A to 15E are cross sectional views collectively showing the manufacturing process of a semiconductor device for Example 6 of the present invention.

### DETAILED DESCRIPTION OF THE INVENTION

The present invention will now be described in detail with reference to the accompanying drawings.

One embodiment of the present invention is directed to a semiconductor device in which an insulating film made of a highly dielectric thin film is formed on a semiconductor substrate and is featured in that nano-crystals are precipitated in the insulating film.

FIG. 3 exemplifies a case where the technical idea of one embodiment according to the present invention is applied to a MOS transistor. In the MOS transistor shown in FIG. 3, a gate insulating film 11 containing a highly dielectric thin film and a gate electrode 12 are formed on a semiconductor substrate 10 such as a silicon substrate. It is desirable for the thickness of the gate insulating film 11 containing a highly dielectric thin film to fall within a range of between 3 nm and 20 nm. Further, source-drain regions 13a, 13b are formed on both sides of the gate electrode 12. The gate insulating film 11 may be formed of a mixed film including a silicon compound containing at least one element selected from the group consisting of an oxygen and a nitrogen, and a metal compound containing a metal other than silicon and at least one element selected from the group consisting of an oxygen and a nitrogen. The entire mixed film is not amorphous, and nano-crystals are formed in the mixed film.

Very small grains of single crystals are collectively called nano-crystals. The size of nano-crystals is about 10 nm or less, for example, and is sufficiently smaller than the gate length Lg.

Whether or not the crystals within the thin film are nano-crystals are determined as follows. Specifically, if an electron beam diffraction ED, in which the diameter of the beam is generally scores of nanometers, is applied to a sample to be measured, a spot-like diffraction image is obtained in the case where the sample is a single crystal, and a ring-like diffraction image (polycrystalline ring) is obtained in the case where the sample is polycrystalline. It should be noted that, if the diameter of the electron beam is diminished to a nanometer order (1 nm to 10 nm), e.g., about 5 nm, the diffraction image forms a spot even in the case of the polycrystal, and a polycrystalline ring can be observed in the case of the microcrystal smaller than the polycrystal. It follows that, in the case of employing electron beam diffraction using an electron beam having a very small diameter of about 5 nm, it is possible to determine whether or not the sample to be measured is microcrystalline depending on whether or not the polycrystalline ring can be observed.

According to a one aspect of the present invention, there is provided a semiconductor device comprising:

a semiconductor substrate, and

a circuit element using an insulating film formed on said semiconductor substrate,

said insulating film containing a silicon compound containing at least one element selected from the group consisting of an oxygen and a nitrogen, and a metal compound containing a metal other than silicon and at least one element selected from the group consisting of an oxygen and a nitrogen, nano-crystals being formed in said insulating film, the size of said nano-crystal being small enough to permit observation of a polycrystalline ring as a diffraction image when an electron beam having a beam diameter of the nanometer order is incident in parallel to said insulating film surface.

As described above, in the semiconductor device of one aspect of the present invention, nano-crystals, not polycrystals, are precipitated in the gate insulating film containing a highly dielectric thin film. In some cases, an amorphous material enters the grain boundary in the insulating film included in the semiconductor device of one aspect according to the present invention. It follows that it is possible to suppress the leakage current derived from the grain boundary.

The nano-crystals may be formed in the insulating film, it is preferable that the size of the largest nano-crystal grain in the insulating film being not larger than the thickness of the insulating film.

The size of the nano-crystal is smaller than the width W of the gate insulating film and is sufficiently smaller than the gate length Lg. When the size of the largest nano-crystal grain in the insulating film is defined to be smaller than the thickness of the insulating film, it is impossible for the grain boundary to extend through the front and back surfaces of the film. Since a plurality of nano-crystals are present in the longitudinal direction of the gate, it is also possible to suppress the nonuniformity in the threshold value and the driving force.

In the semiconductor device according to any of the embodiments of the present invention, it is desirable for nano-crystal grains of an oxide, a nitride or an oxynitride of a metal other than silicon to be dispersed in the gate insulating film in order to obtain a high dielectric constant.

The insulating film may be a mixed film including a silicon compound containing at least one element selected from the group consisting of an oxygen and a nitrogen, and a metal compound containing a metal other than silicon and at least one element selected from the group consisting of an oxygen and a nitrogen.

Where a mixed film containing titanium oxide and silicon oxide is used as the gate insulating film, the leakage current is diminished and the dielectric constant is increased with an increase in the silicon content of the mixed film. It follows that it is desirable for the gate insulating film to be formed of a mixed film containing titanium oxide and silicon oxide. The particular mixed film can be formed by a sputtering method using a mixed sintered body containing titanium oxide and silicon oxide used as a target. According to the experiment conducted by the present inventors, the leakage current can be sufficiently lowered and the relative dielectric constant is increased to a level not lower than 50, if the silicon content of the mixed film is not lower than 15%. It follows that it is desirable for the average silicon content of the mixed film, i.e., the value of Si/(Si+Ti), to be not lower than 15%.

As described above, it is desirable for the average silicon content of the mixed film, i.e., the value of Si/(Si+Ti), to be not lower than 15%. In this case, the effect produced by nano-crystallization is further improved. Further, it is desirable for the silicon content, i.e., the value of Si/(Si+Ti), to be not higher than 80%. In this case, it is possible to obtain a relative dielectric constant εᵣ, which is larger than 10, required for the highly dielectric film. It is more desirable for the silicon content, i.e., Si/(Si+Ti), to fall within a range of between 15% and 60%. In this case, it is possible to obtain a high relative dielectric constant.

It is desirable for the particle diameter of the nano-crystal within the mixed film to be not larger than 10 nm, more preferably, to fall within a range of between 1 nm and 10 nm. In this case, it is possible to suppress the nonuniformity in the threshold value and the driving force of the very small MOS transistor that is sized smaller than 50 nm.

The insulating film included in the semiconductor device of one embodiment of the present invention can be formed by forming on a semiconductor substrate a mixed film containing at least one material selected from the group consisting of silicon oxide, silicon nitride and silicon oxynitride and at least one material selected from the group consisting of an oxide, a nitride and an oxynitride of a metal other than silicon under temperatures at which the crystallization does not take place, followed by applying a heat treatment to the resultant mixed film so as to permit the nano-crystalline metal oxides to precipitate in the mixed film.

It is desirable for the heat treatment for precipitating the nano-crystalline metal oxides to be carried out at a pressurized atmosphere higher than the atmospheric pressure of room temperature, i.e., under a pressurized atmosphere higher than 100 kPa. In this case, it is possible to suppress the diameter of the nano-crystals to a level not larger than several nanometers.

It is desirable to decrease the thickness of the insulating film by partly etching the nano-crystals precipitated by the heat treatment.

Further, it is desirable to form, before formation of the mixed film, a thin film for preventing oxidation on the underlying substrate, e.g., a silicon substrate. To be more specific, it is desirable to form an oxynitride film by a heat treatment using, for example, a NO gas.

As described above, in one embodiment of the present invention, a highly dielectric thin film formed of a mixed film containing at least one material selected from the group consisting of silicon oxide, silicon nitride and silicon oxynitride and at least one material selected from the group consisting of an oxide, a nitride and an oxynitride of a metal other than silicon is used as a gate insulating film, and nano-crystals are precipitated in the thin film. The particular construction of one embodiment of the present invention makes it possible to suppress the leakage current derived from the grain boundary and to suppress the nonuniformity in the threshold value and the driving force. It follows that it is possible to improve the characteristics of the MOS transistor, etc.

### EXAMPLE 1

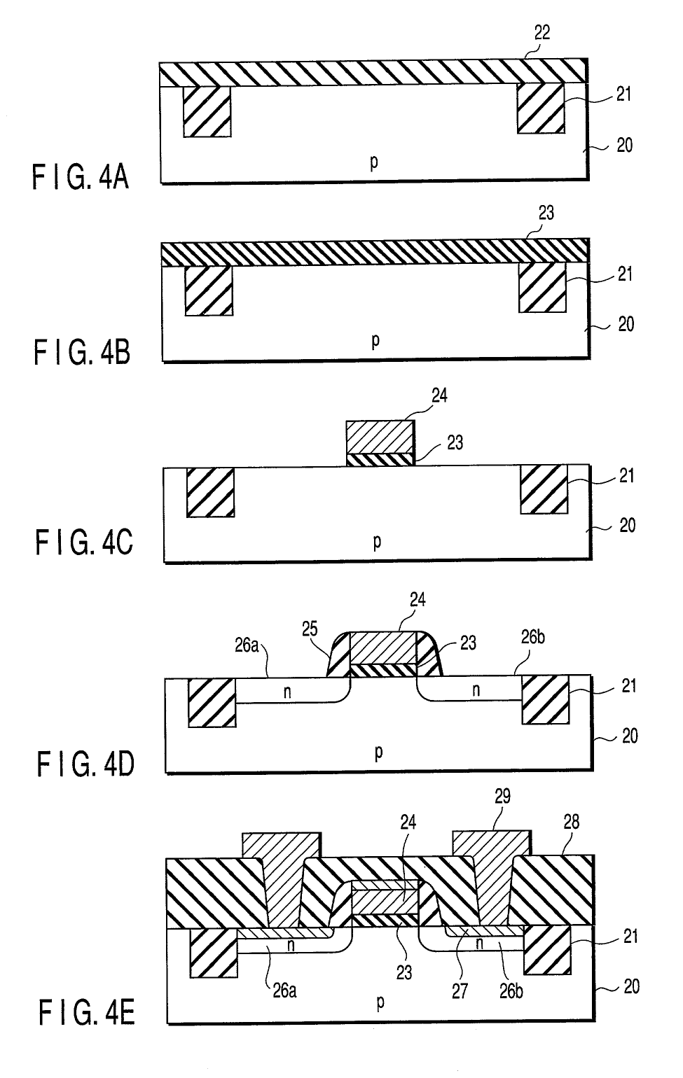

FIGS. 4A to 4E are cross sectional views collectively showing the manufacturing process of a semiconductor device for Example 1 of the present invention.

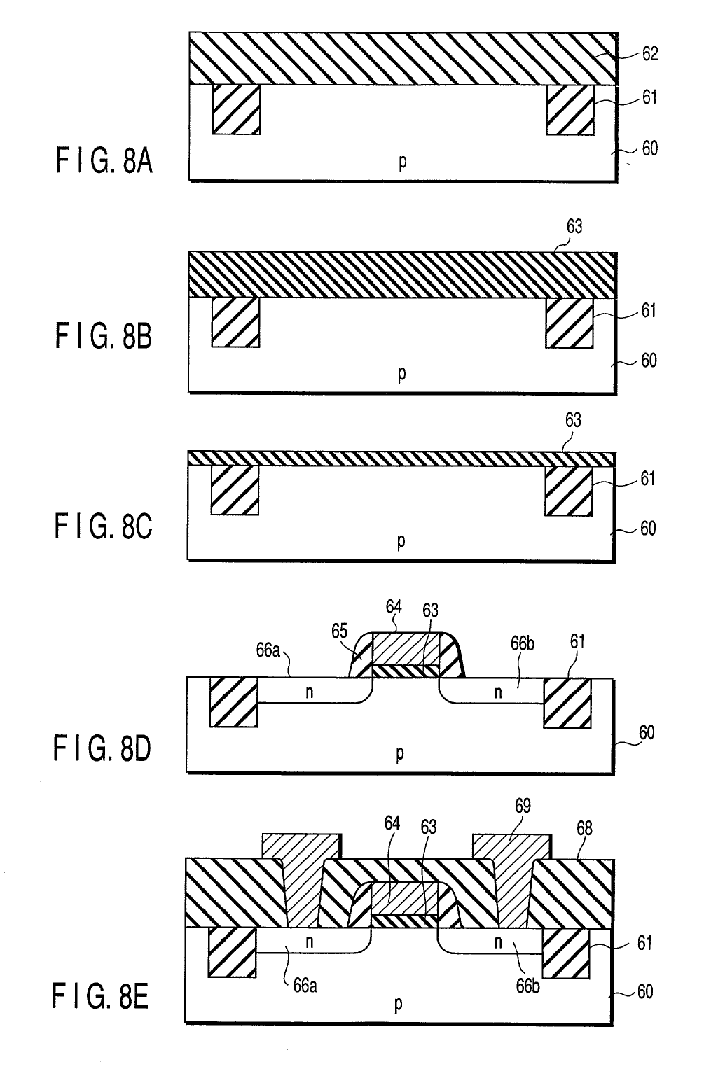

The processes shown in FIGS. 4A to 4E and in FIGS. 8A to 8E, 9 and 10A to 10D referred to herein later are directed to n-channel MOSFETs. However, the present invention is not limited to an n-channel MOSFET. As a matter of fact, it is possible for a p-channel MOSFET to be formed together on the same substrate, and the present invention is described herein later bearing in mind that the p-channel MOSFET is formed by the same process. Therefore, it is assumed that the silicon substrate is doped with a p-type impurity unless otherwise specified. Of course, the technical idea of the present invention can be applied to an SOI (Silicon On Insulator) MOSFET and a vertical MOSFET in which the channel region extends in a direction perpendicular to the substrate surface and the electrons and holes are migrated in a direction perpendicular to the substrate surface.

In the first step, a SiO₂ film 21 for the trench element isolation is formed on a p-type silicon substrate 20, followed by depositing a mixed film 22 of TiO₂/SiO₂ on the entire surface under temperatures at which crystallization does not take place, e.g., at room temperature, as shown in FIG. 4A. The mixed film 22 can be deposited by any of a vapor deposition method, an ordinary RF sputtering method, a sputtering method using a helical coil, a sol-gel method, a laser ablation method and a CVD method. Naturally, the temperature and the forming conditions of the mixed film 22 differ depending on the method of depositing the mixed film 22.

In Example 1, the mixed film 22 was deposited by a sputtering method. To be more specific, a target is prepared by finely pulverizing TiO₂ and SiO₂, followed by sintering the pulverized materials mixed at a predetermined mixing ratio. The mixing ratio of Si/(Ti+Si) is set at 20%. After the target is positioned to face the silicon substrate, a sputtering was performed for 30 minutes under a mixed gas atmosphere of Ar and O₂ (Ar: 20 sccm; O₂: 2 sccm) so as to deposit the mixed film 22 in a thickness of 20 nm. The sputtering was performed at room temperature with the power set at 100 W.

In the next step, a heat treatment was applied to the mixed film 22 at 800° C. for 30 seconds under an Ar gas atmosphere so as to convert the mixed film 22 into a highly dielectric film 23 containing nano-crystals, as shown in FIG. 4B.

Then, a patterned gate electrode 24 and a patterned highly dielectric insulating film 23 are obtained as shown in FIG. 4C. The gate electrode 24 and the highly dielectric insulating film 23 can be formed as follows. In the first step, a metal silicide film, e.g., a SiGe film 24, is deposited in a thickness of 100 nm as the gate electrode at 550° C. under a mixed gas atmosphere containing SiH₄ and GeH₄. Then, a resist pattern is formed by photolithography, followed by performing an acidic ion etching by using the resultant resist pattern as a mask under an atmosphere of CF₄+O₂ so as to process the SiGe film 24 into the shape of a gate electrode. Then, the highly dielectric insulating film 23 containing the nano-crystals is processed by using a solution containing HF.

Further, an As ions are implanted with a dose of 1×10¹⁴ cm⁻² under an accelerating energy of 300 eV by using the SiGe film 24 as a mask, as shown in FIG. 4D. Then, a SiN film is deposited on the entire surface, followed by etching back the SiN film on the entire surface by RIE so as to form a gate side wall SiN film 25 in a thickness of 10 nm. Further, As ions are implanted again at a dose of 1×10¹⁵ cm⁻² under an accelerating energy of 10 keV with the SiGe film 24 and the SiN film 25 used as a mask. Still further, an RTA (rapid temperature annealing) is applied at a temperature between 900° C. and 1200° C. for about 1 to 30 seconds so as to form source-drain regions 26a, 26b and to add an n-type impurity to the SiGe film 24 forming the gate electrode.

Then, a CoSi₂ film 27 is deposited on each of the source region, the drain region and the gate electrode by deposition of Co/heat treatment/etching, as shown in FIG. 4E. Finally, a SiO₂ film 28 acting as an interlayer insulating film is deposited on the entire surface by using, for example, TEOS, followed by making contact holes communicating with the source-drain regions in the SiO₂ layer 28. Further, a wiring layer 29 of Al/TiN/Ti or Cu/TiN/Ti is formed to fill the contact holes. In the subsequent process, the steps for forming the second wiring layer et seq. are carried out so as to finish the manufacture of an LSI.

In this Example 1, nano-crystals in the highly dielectric insulating film 23 are formed immediately after depositing the mixed film. However, it is possible to form the nano-crystals after depositing the gate electrode or after patterning the highly dielectric insulating film. Alternatively it is also possible to form the nano-crystals during activating the impurity doped in the semiconductor substrate.

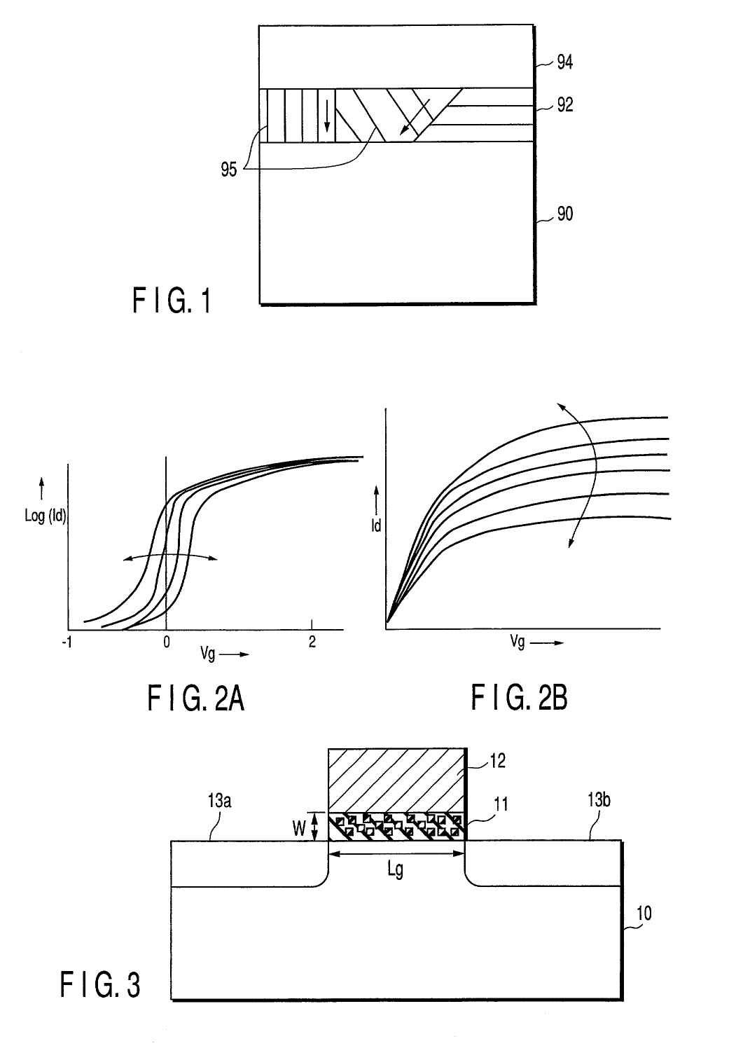

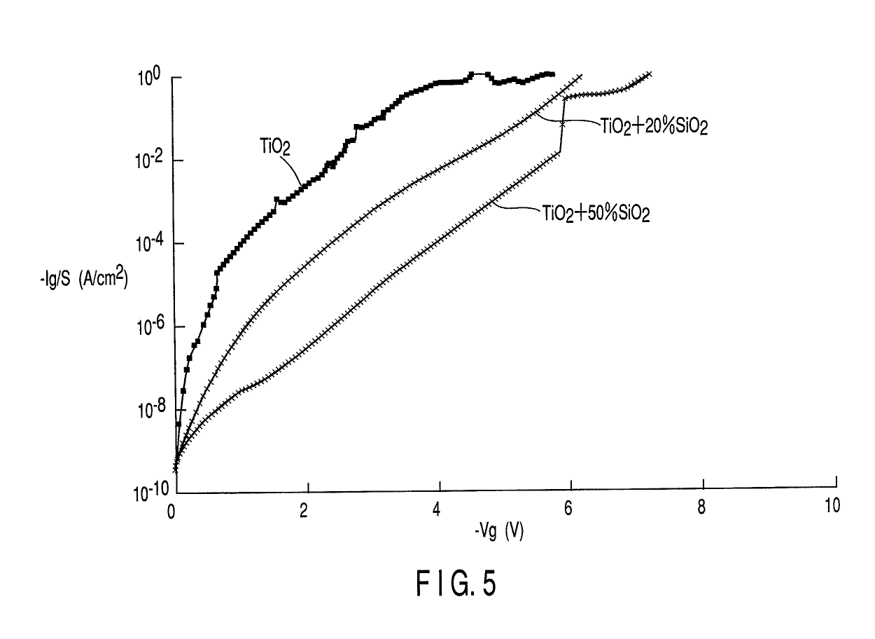

FIG. 5 is a graph showing the change in the leakage current through the TiSiO film having a thickness of 100 nm relative to the silicon content of the mixed film. As apparent from the graph, the leakage current is decreased with increase in the silicon content to exceed 15%. The decrease in the leakage current is brought about because the TiSiO film, which is columnar under the polycrystalline state as shown in FIG. 1, is formed of nano-crystals of the nanometer order in the case where the silicon content is not lower than 15%. The present inventors have confirmed the particular phenomenon by observation with an electron microscope of high resolution.

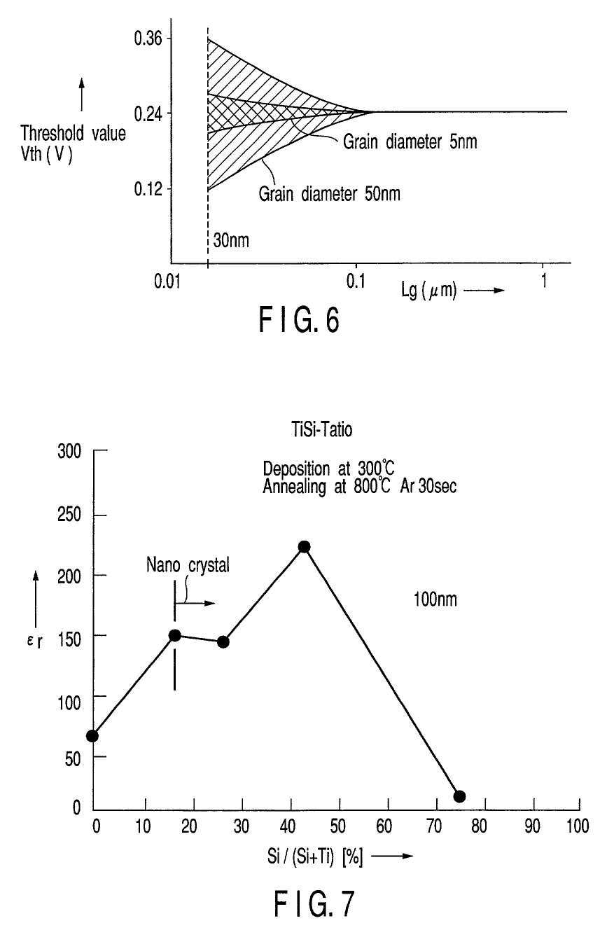

FIG. 6 shows the estimated nonuniformity of the threshold voltage, which was calculated in respect of two crystal grain diameters of TiO₂. Where the size of the gate electrode is diminished, the threshold value is made widely nonuniform to fall within a range of between 0.12 V and 0.36 V in the case of using a film formed of ordinary crystal grains having a grain diameter of 50 nm. On the other hand, FIG. 6 shows that, where the crystal grain diameter is decreased to 5 nm, the nonuniformity of the threshold value is narrowed to fall within a range of 0.24 V±0.04 V. This supports that the influence of the anisotropy in the relative dielectric constant owing to the direction of the crystal axis of TiO₂ is suppressed by the miniaturization of the crystal grains.

The present inventors have also found through extensive research, that the TiO₂/SiO₂ mixed film formed of nano-crystals exhibits a very high relative dielectric constant in the case where the silicon content of the mixed film is not lower than 15%. This is highly effective for the manufacture of the next generation LSIs, i.e., an LSI having a gate length Lg of 10 nm, in that it is possible to increase the capacitance between the gate and the substrate while suppressing the leakage current, i.e., power consumption of the LSI.

As described above, in Example 1, a TiO₂/SiO₂ mixed film containing 20% of silicon is used as the gate insulating film 23, and nano-crystals are precipitated in the mixed film. Further, an amorphous material enters the grain boundary, with the result that it is possible to suppress the leakage current derived from the grain boundary. It should also be noted that, since a plurality of nano-crystals are present in the longitudinal direction of the gate, it is possible to suppress the nonuniformity in the threshold value and the driving force even in a very small MOS transistor sized not larger than 50 nm. Further, it has also been found possible to suppress the SILC after application of the current stress.

### EXAMPLE 2

Example 2 is a modification of Example 1 and differs from Example 1 in the step of forming the nano-crystals. The manufacturing process of the semiconductor device for Example 2 can be described with reference to FIGS. 4A to 4E referred to previously in conjunction with Example 1.

In the first step, the structure shown in FIG. 4A is obtained by depositing, by the method similar to that described previously in conjunction with Example 1, a mixed film 22 containing a TiO₂ and SiO₂ on a p-type silicon substrate 20 having a SiO₂ film 21 for the element isolation formed therein under temperatures at which crystallization does not take place.

Then, in the step shown in FIG. 4B, a highly dielectric insulating film 23 containing nano-crystals was formed under a lower temperature by applying a heat treatment at 600° C. for 30 seconds under a high pressure of 10 MPa. By forming the highly dielectric insulating film 23 under a low temperature, it is possible to suppress the diffusion of the impurity in the channel region and to make finer the nano-crystals within the highly dielectric insulating film 23. The subsequent steps are equal to those for Example 1, which are shown in FIGS. 4C to 4E, thereby manufacturing an LSI.

Example 2 also produces the effects similar to those produced by Example 1 described previously. In addition, in Example 2, it is possible to suppress the diffusion of the impurity so as to make finer the crystal grains of the nano-crystals because the heat treatment for forming the nano-crystals is carried out under a high pressure. According to the experiment conducted by the present inventors, the particular effects can be produced if the pressure in the heat treating step is set at 100 kPa or higher.

### EXAMPLE 3

FIGS. 8A to 8E are cross sectional views collectively showing the manufacturing process of the semiconductor device for Example 3. Reference numerals 60 to 69 shown in FIGS. 8A to 8E correspond to reference numerals 20 to 29 shown in FIGS. 4A to 4E, respectively.

In the first step, a mixed film 62 containing TiO₂ and SiO₂ is deposited on a p-type silicon substrate 60 having a SiO₂ film 61 for the element isolation formed therein in advance under temperatures at which crystallization does not take place. This step is equal to that for Example 1. In Example 3, however, the mixed film 62 has a large thickness of 100 nm.

In the next step, a heat treatment was applied at 800° C. for 30 seconds under an Ar gas atmosphere so as to convert the mixed film 62 into a highly dielectric insulating film 63 containing nano-crystals of TiO₂, as shown in FIG. 8B. Then, the thickness of the highly dielectric insulating film 63 was decreased to 20 nm by the treatment with a solution containing HF, e.g., a mixed solution containing 1 part of a 47% HF and 10 parts of H₂O, for 5 minutes, as shown in FIG. 8C. It is also possible to decrease the thickness of the highly dielectric insulating film 63 before the heat treatment for forming the nano-crystals.

Further, a gate electrode of, for example, a SiGe film 64 was deposited by a CVD method in a thickness of 100 nm, followed by processing the SiGe film 64 by photolithography into the shape of the gate electrode, as shown in FIG. 8D. Still further, a gate side wall SiN film 65 was formed, followed by forming source-drain regions 66a, 66b as in Example 1.

In the subsequent steps, a SiO₂ film 68 acting as an interlayer insulating film was formed on the entire surface, followed by making contact holes in the SiO₂ film 68 and subsequently forming a wiring layer 69 of Al/TiN/Ti or Cu/TiN/Ti structure as in Example 1 so as to finish manufacture of a MOS transistor, as shown in FIG. 8E.

The etch back step of the highly dielectric insulating film 63 containing nano-crystals, which was employed in Example 3, can also be applied to the case other than the case where the etch back is performed uniformly over the entire surface. It is possible to apply the etch back to only a part, e.g., to only the p-channel MOS, to only the portion corresponding to the logic SLI in a mixed LSI, or to only the portion corresponding to the memory LSI.

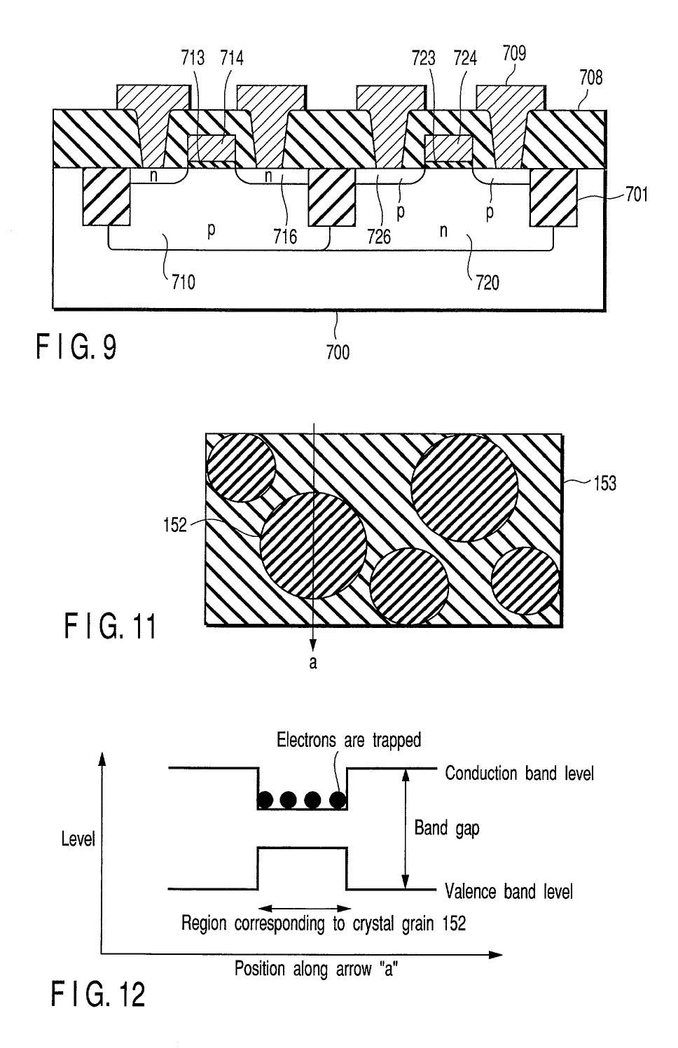

FIG. 9 is a cross sectional view showing the construction of an element in which an n-channel MOSFET and a p-channel MOSFET are arranged on the same substrate. Reference numeral 700 shown in FIG. 9 denotes a silicon substrate, reference numeral 701 denotes an element isolating insulating film, reference numeral 708 denotes an interlayer insulating film, reference numeral 709 denotes a wiring layer, reference numeral 710 denotes a p-type well, reference numeral 720 denotes an n-type well, each of reference numerals 713 and 723 denotes a gate insulating film, each of reference numerals 714 and 724 denotes a gate electrode, each of reference numerals 716 and 726 denotes source-drain regions. As apparent from the drawing, the members 710 to 716 referred to above collectively form an n-channel MOSFET, and the members 720 to 726 referred to above collectively form a p-channel MOSFET.

The etch back of the highly dielectric insulating film containing nano-crystals is applied to only the n-channel MOSFET region in the following case. Where the work function of the gate electrode is on the side of the valence band relative to the intrinsic Fermi level Ei of the band gap of Si, the threshold value |Vₜₕₙ| of the n-channel is rendered larger than the threshold value |Vₜₕₚ| of the p-channel, with the result that the timing of the CMOS logic is rendered unbalanced.

In this case, it is possible to diminish the threshold value |Vₜₕₙ| of the n-channel so as to moderate the unbalance by decreasing the thickness of the gate insulating film on the side of only the n-channel of the n-channel MOSFET. Of course, where the work function of the electrode is on the side of Ec relative to Ei, the thickness of the gate insulating film on the side of the p-channel is decreased. On the other hand, it is conceivable to decrease the thickness of the gate insulating film in a logic LSI requiring a high speed operation and to use a thick film in a memory LSI in which the leakage current is preferentially minimized.

### EXAMPLE 4

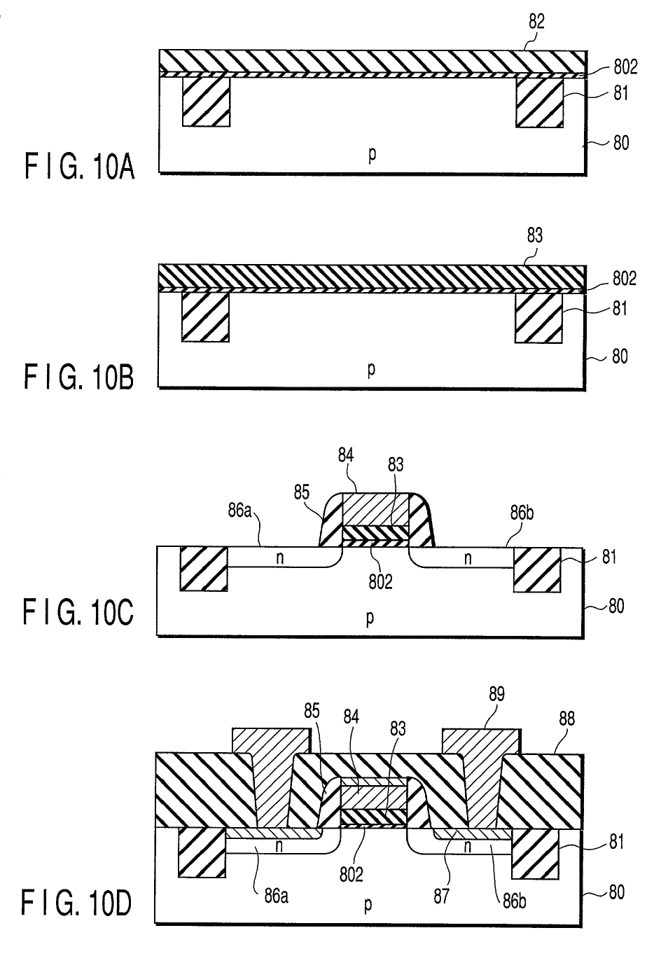

FIGS. 10A to 10D are cross sectional views collectively showing the manufacturing process of a semiconductor device for Example 4 of the present invention. Incidentally, reference numerals 80 to 89 shown in FIGS. 10A to 10D correspond to reference numerals 20 to 29 shown in FIGS. 4A to 4E, respectively.

In the first step, a SiO₂ film 81 for the element isolation is formed on a p-type silicon substrate 80, followed by an ion implantation for controlling the threshold value of the MOS transistor, as shown in FIG. 10A. Then, after the oxide film other than the SiO₂ film 81 is completely removed, a heat treatment is applied at 850° C. for 5 seconds using a NO gas so as to form an oxynitride film 802 having a thickness of 0.7 μm, followed by forming a mixed film 82 of a TiO₂/SiO₂ structure. Since the oxynitride film 802 is formed on the silicon substrate 80 as shown in FIG. 10A, a further oxidation of the surface of the silicon substrate is suppressed even if a sputtering is performed under an atmosphere containing O₂.

In the next step, a highly dielectric insulating film 83 containing nano-crystals of TiO₂ is formed by a heat treatment at 800° C. for 30 seconds under an Ar atmosphere, as shown in FIG. 10B. In the subsequent process, the formation of the gate electrode 84 and the side wall SiN film 85, the ion implantation for forming the source-drain regions, and the formation of an interlayer insulating film 88 and a wiring layer 89 are carried out as in Example 1, as shown in FIGS. 10C and 10D, thereby finishing the manufacture of an LSI.

In this Example 4, nano-crystals in the highly dielectric insulating film 83 are formed immediately after depositing the mixed film. However, it is possible to form the nano-crystals after depositing the gate electrode or after patterning the highly dielectric insulating film. Alternatively it is also possible to form the nano-crystals during activating the impurity doped in the semiconductor substrate.

FIG. 11 schematically shows the nano-crystals in the case of using the mixed film defined in one example of the present invention. Reference numeral 152 in FIG. 11 denotes the nano-crystal, and reference numeral 153 denotes the mixed film. The mixed film 153 containing these nano-crystals 152 can be formed by forming a mixed film in a thickness of about 100 nm by a sputtering method using a mixed sintered body of TiO₂ and SiO₂ as a target, followed by an annealing treatment at 800° C. for 30 seconds under an Ar gas atmosphere. In the annealing step, the nano-crystals 152 of TiO₂ are precipitated. It is possible to decrease the grain diameter of the TiO₂ crystal grains by increasing the SiO₂ concentration in the mixed film 153. It follows that it is possible to suppress the nonuniformity in the threshold value dependent on the anisotropy of εᵣ referred to previously and in the current driving force in the case of forming a MOS transistor having a gate length Lg of 30 nm. It is also possible to suppress the leakage current flowing through the crystal grain boundary by increasing the SiO₂ concentration.

However, it has also been clarified by further research conducted by the present inventors that the trapping of electric charge tends to take place easily in the mixed film containing the nano-crystals, which possibly invites the problem of fluctuation in the threshold value of the MOSFET and deterioration in the reliability of the gate insulating film. The trapping of the electric charge is derived from the fact that the energy level of the TiO₂ nano-crystal 152 is lower than that of the peripheral region, in which the silicon oxide is contained in a large amount, of the nano-crystal 152. To be more specific, where the size of the TiO₂ nano-crystal 152 in the thickness direction of the mixed film 153 is smaller than the thickness of the mixed film 153, the energy level of the TiO₂ nano-crystal is lower than that in the peripheral region so as to form a quantum well. The electrons are trapped in the quantum well. It is also conceivable for the holes to be trapped in the quantum well.

FIG. 12 schematically shows the energy levels in the thickness direction in the TiO₂ nano-crystal 152 and the mixed film 153 around the nano-crystal 152. The particular phenomenon is considered to take place not only in TiO₂ but also in a mixed film containing a highly dielectric metal oxide and silicon oxide that are subjected to phase separation after the heat treatment.

The present inventors have found that, in order to prevent the electric charge from being trapped in the insulating film containing nano-crystals, it is effective for a part of the periphery of at least one of the nano-crystals to be positioned within a distance of 0.7 nm from the interface with the insulating film.

To be more specific, in another embodiment of the present invention, a part of the periphery of at least one of the nano-crystals may be positioned within a distance of 0.7 nm from the interface of the insulating film.

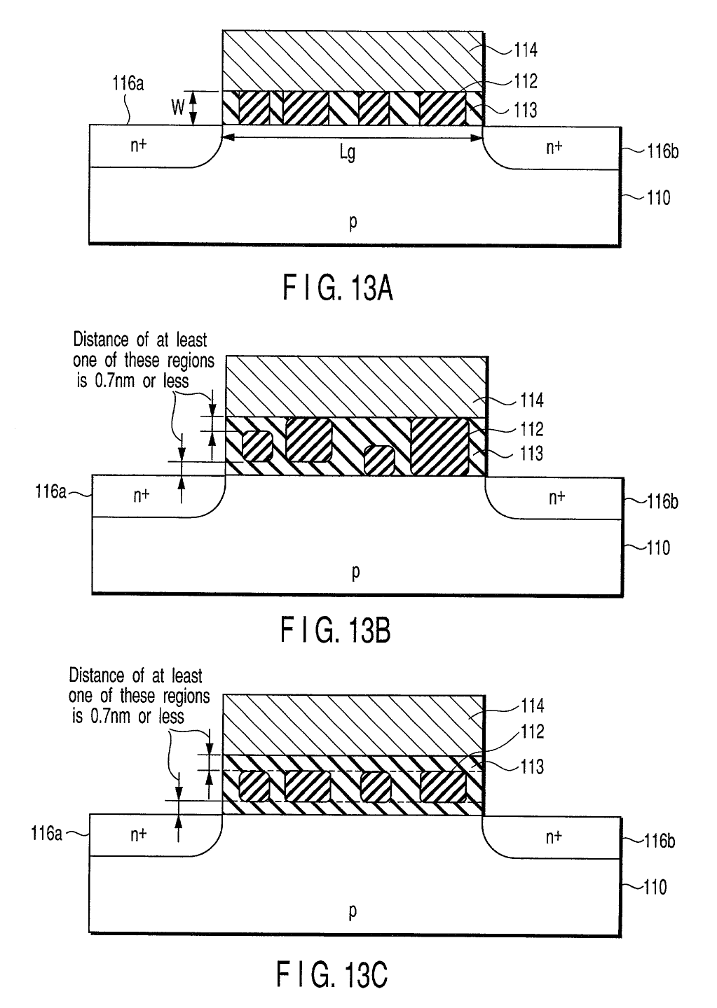

FIGS. 13A to 13C collectively show a MOS transistor to which the technical idea of another embodiment of the present invention is applied. In the MOS transistor shown in FIGS. 13A to 13C, a gate insulating film 113 containing a highly dielectric film and a gate electrode 114 are formed successively on a semiconductor substrate 110 such as a silicon substrate. Further, source-drain regions 116a, 116b are formed on both sides of the gate electrode 114. It should be noted that the gate insulating film 113 may be a mixed film including a silicon compound containing at least one element selected from the group consisting of an oxygen and a nitrogen, and a metal compound containing a metal other than silicon and at least one element selected from the group consisting of an oxygen and a nitrogen. The entire region of such a mixed film is not amorphous, and a large number of nano-crystals 112 are precipitated in the mixed film. In the embodiment of the present invention, it is most desirable for the nano-crystals to be formed in a manner to extend through the front and back surfaces of the mixed film 113. However, it is not absolutely necessary for all the nano-crystals to extend through the front and back surfaces of the mixed film 113. It suffices for a major portion of the nano-crystals to extend through the front and back surfaces of the mixed film 113. To be more specific, it is possible to obtain a sufficient effect if at least 50% by volume of the nano-crystals are formed in a manner to extend through the front and back surfaces of the mixed film 113.

As described previously, very small single crystals are collectively called nano-crystals. To be more specific, the nano-crystal is not larger than about 10 nm and is sufficiently smaller than the gate length Lg of the MOSFET. Whether or not the crystals in the thin film are nano-crystals can be determined by an electron beam diffraction, as described previously.

Where a mixed film containing titanium oxide and silicon oxide is used as the gate insulating film, the leakage current can be diminished and the relative dielectric constant of the mixed film can be increased with an increase in the silicon content of the film, as described previously. It follows that it is desirable for the mixed film to be a mixed film containing titanium oxide and silicon oxide. The particular mixed film can be formed by a sputtering method with a sintered body containing titanium oxide and silicon oxide used as a target. The present inventors have experimentally confirmed that, if the silicon content of the mixed film is increased to 15% or more, the leakage current can be sufficiently lowered and the relative dielectric constant is increased to 50 or more. It follows that it is desirable for the silicon content of the mixed film, i.e., the value of Si/(Si+Ti), to be not lower than 15%.

As described above, it is desirable for the silicon content of the mixed film, i.e., the value of Si/(Si+Ti), to be not lower than 15%. In this case, the effect produced by the nano-crystallization can be enhanced. It is more desirable for the value of Si/(Si+Ti) to be not higher than 80%. In this case, it is possible to obtain the relative dielectric constant εᵣ larger than 10, which is required for a highly dielectric film. It is further more desirable for the value of Si/(Si+Ti) to fall within a range of between 15% and 60%. In this case, it is possible to obtain a further higher relative dielectric constant.

As explained by quantum theory, where Si is brought into contact with SiO₂, the wave function of Si oozes into SiO₂ by about 0.7 nm (D. A. Muller et al., NATURE, 399 (1999) 758). It follows that, where the gate electrode is formed of polycrystalline silicon (polysilicon), it is possible for the TiO₂ crystal grains to be surrounded by a SiO₂ layer having a thickness of about 0.7 nm in a mixed film in which a material having an energy level lower than that of the main medium of SiO₂, e.g., TiO₂ crystal grains, is precipitated in the SiO₂ layer. FIG. 13B shows the construction in such a case. Further, in a MOS device, no problem is generated even if a main interfacial layer of SiO₂ is formed at the interface between the silicon substrate and the gate insulating film or at the interface between the gate electrode and the gate insulating film, as long as the thickness of the main interfacial layer of SiO₂ is not larger than the value noted above. FIG. 13C shows the construction for such a case.

Incidentally, where the material of the gate electrode and the substrate is not silicon or where the mixed film contains materials other than TiO₂ and SiO₂, the oozing length of the wave function also differs. For example, if SiO₂ is replaced by a material having a lower energy level, the oozing length of the wave function of silicon is rendered large. In this case, the distance between the nano-crystal and the interface of the mixed film is not limited to a range not larger than 0.7 nm and can be increased in accordance with the oozing length of the wave function.

As described above, in the another embodiment of the present invention, the crystals precipitated in the gate insulating film formed of a highly dielectric film are not polycrystals but single crystals and are sufficiently smaller than the gate length Lg. Also, an amorphous material enters the crystal grain boundary. As a result, it is possible to suppress the leakage current derived from the crystal boundary. In addition, a plurality of nano-crystals are present in the longitudinal direction of the gate, and the size of the nano-crystal is substantially equal to the width W of the mixed film such that crystal boundary extends through the front surface and the back surface of the film. It follows that it is possible to markedly decrease the trap density that is dependent on the energy level of the nano-crystal present in the mixed film. In order to obtain a high dielectric constant, it is desirable for at least the nano-crystals of a metal oxide to be dispersed in the gate insulating film.

The semiconductor device shown in FIGS. 13A to 13C is equal to that shown in FIG. 3, except that a part of the periphery of at least one of the nano-crystals dispersed in the gate insulating film is present within a distance of 0.7 nm from the interface of the insulating film.

The insulating film in the particular semiconductor device can be formed as follows. Specifically, in the first step, a mixed film containing at least one of silicon oxide, silicon nitride and silicon oxynitride and at least one of an oxide, a nitride and an oxynitride of a metal other than silicon is formed on a semiconductor substrate under a temperature at which crystallization does not take place. Then, a heat treatment is applied so as to precipitate a plurality of nano-crystals of the metal oxide in the mixed film and to grow the nano-crystals such that a part of the periphery of at least one of the nano-crystals is positioned within a distance of 0.7 nm from the interface of the insulating film, thereby obtaining a desired insulating film.

For achieving precipitation of the nano-crystalline metal oxide in the particular position within the mixed film, a mixed film containing TiO₂ and SiO₂ is formed first, followed by annealing the resultant mixed film in an Ar atmosphere of an atmospheric pressure. Alternatively, it is possible to apply the annealing treatment at a pressure higher than the atmospheric pressure, e.g., at a pressure higher than 100 kPa.

For forming the nano-crystals, it is desirable to apply the annealing treatment at an atmospheric pressure and the temperature falling within a range of between 800° C. and 1,000° C. Alternatively, it is possible to apply the annealing treatment at a high pressure of about 10 MPa and temperatures falling within a range of between 600° C. and 1,000° C.

It is also desirable to form a thin film for preventing oxidation on the underlying substrate, e.g., a silicon substrate, before formation of the mixed film. To be more specific, it is desirable to form an oxynitride film by heat treatment using a NO gas. If the oxidation preventing film sufficiently performs its function, it is possible to carry out the annealing treatment under high temperatures within an oxygen-containing atmosphere.

It is desirable to etch a part of the insulating film, in which nano-crystals have been precipitated by heat treatment, so as to decrease the thickness of the insulating film to a desired level.

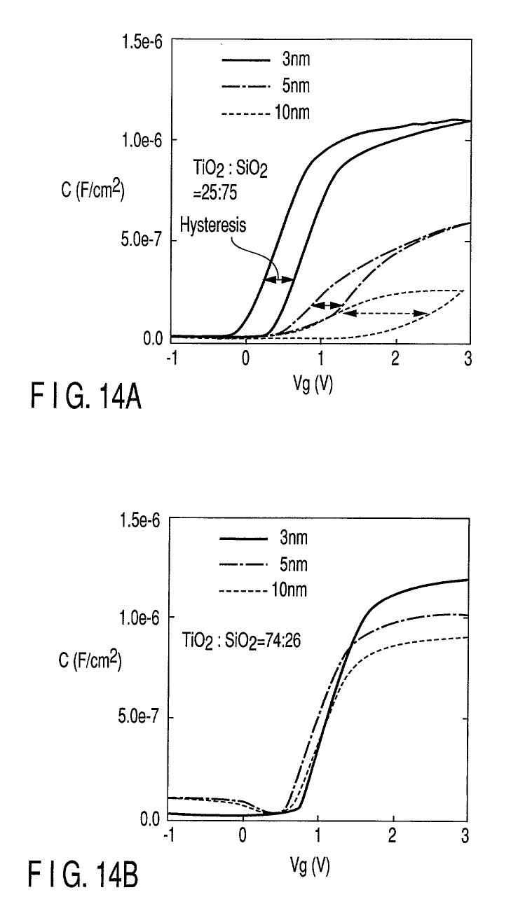

FIGS. 14A and 14B show C-V (capacitance-gate voltage) curves of the mixed layer containing the nano-crystals thus formed. In this case, a SiO₂/TiO₂ mixed film having a thickness of about 3 nm, 5 nm or 10 nm was formed as an insulating film on an n-type silicon substrate. As shown in FIG. 14A, the hysteresis is diminished with a decrease in the thickness of the film in the case where the SiO₂ content of the mixed film is 75%. In this case, the average grain diameter of the nano-crystals was found to be about 2 nm. This indicates that, since the grain diameter of the nano-crystal is sufficiently smaller than the thickness of the mixed film, a recess of the energy level is formed in the vicinity of the crystal grain, thereby trapping electric charge.

On the other hand, where the SiO₂ content was 26%, the hysteresis was scarcely recognized, as shown in FIG. 14B. The particular phenomenon is derived from the fact that the average grain diameter of the nano-crystals was about 10 nm and, thus, the phenomenon as shown in FIG. 14A did not take place. Incidentally, where the film thickness is 3 nm or 5 nm, the size in the horizontal direction of the nano-crystal is about 10 nm. However, the size of the nano-crystal in the thickness direction of the film is naturally substantially equal to the film thickness.

### EXAMPLE 5

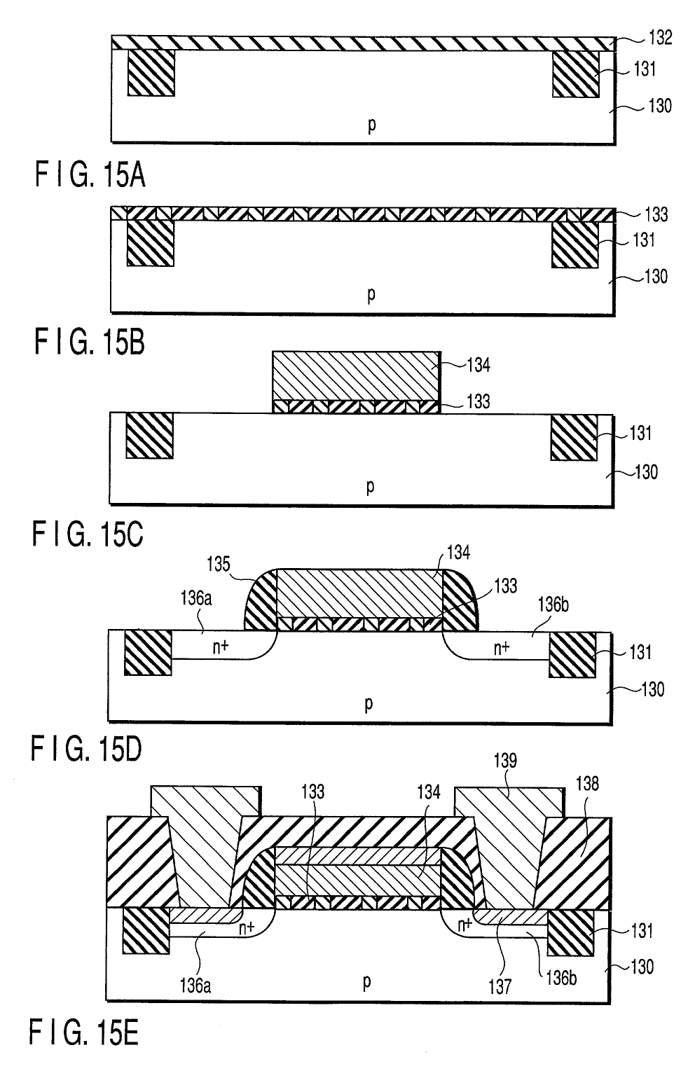

FIGS. 15A to 15E are cross sectional views collectively showing the manufacturing process of the semiconductor device for Example 5.

Incidentally, FIGS. 15A to 15E are directed to an n-channel MOSFET. However, the present invention is not limited to the n-channel MOSFET. As a matter of fact, a p-channel MOSFET is also formed on the same substrate, and the present invention is described herein later bearing in mind that the p-channel MOSFET is formed by the same process. Of course, the technical idea of the present invention can be applied to an SOI (Silicon On Insulator) MOSFET and a vertical MOSFET in which the channel region extends in a direction perpendicular to the substrate surface and the electrons and holes are migrated in a direction perpendicular to the substrate surface.

In the first step, a SiO₂ film 131 for the trench element isolation is buried in a p-type silicon substrate 130, followed by depositing a TiO₂/SiO₂ mixed film 132 on the entire surface under temperatures at which crystallization does not take place, e.g., at room temperature, as shown in FIG. 15A. The mixed film 132 can be deposited by any of a vapor deposition method, an ordinary RF sputtering method, a sputtering method using a helical coil, a sol-gel method, a laser ablation method and a CVD method. Naturally, the temperature and the forming conditions of the mixed film 132 differ depending on the method of depositing the mixed film 132.

In the sputtering method using a helical coil, a target is prepared by finely pulverizing TiO₂ and SiO₂, followed by sintering the pulverized materials mixed at a predetermined mixing ratio. The mixing ratio of Si/(Ti+Si) is set at 20%. After the target is positioned to face the silicon substrate, a sputtering was performed for 10 minutes under a mixed gas atmosphere of Ar and O₂ (Ar: 20 sccm; O₂: 2 sccm) so as to deposit the mixed film 132 in a thickness of 5 nm. The sputtering was performed at room temperature with the power set at 100 W.

In the next step, a heat treatment was applied to the mixed film 132 at 800° C. for 30 seconds under an Ar gas atmosphere so as to convert the mixed film 132 into a highly dielectric insulating film 133 containing nano-crystals, as shown in FIG. 15B. The heating conditions were controlled to permit most of the nano-crystals to have a grain diameter of about 5 nm in an attempt to realize the state shown in FIG. 13A. As a result, it was possible to avoid the problem that an electric charge was trapped in the insulating film. Also, if the heat treating temperature falls within a range of between 800° C. and 1,000° C. it was possible to grow sufficiently large nano-crystals.

It is most desirable for all the nano-crystals to have a size substantially equal to the thickness of the film. However, it is not absolutely necessary for all the nano-crystals to have a size substantially equal to the thickness of the film. Even if nano-crystals having a small size are included, there is no problem if the amount of the small nano-crystals is small. To be more specific, it is possible to obtain a sufficient effect, if at least 50% by volume of the nano-crystals have a size substantially equal to the thickness of the film. Incidentally, the volume ratio of the nano-crystals having a size substantially equal to the thickness of the film can be obtained by measuring the size of each crystal and the distance of the crystal from the interface of the insulating film by TEM observation.

Alternatively, the grain diameter and frequency of the crystals as well as the average thickness of the insulating film are obtained by X-ray diffractometry on the assumption that the crystals are spherical (A. Benedetti et al., J. Appl. Cryst., 21 (1988), 543). The sum of the volume of the crystals larger than the value obtained by subtracting 1.4 nm from the thickness of the insulating film is obtained. It is difficult to obtain the distance from the interface of the insulating film for the individual crystals. However, in order to allow a part of the peripheral portion of at least one crystal smaller by 1.4 nm than the thickness of the insulating film to be positioned at least 0.7 nm apart from the interface of the insulating film, it is necessary for the crystal to be positioned exactly in the center of the insulating film. A part of the peripheral portion of a larger crystal is positioned within 0.7 nm from the interface of the insulating film without fail. Incidentally, the hysteresis loop formed by the C-V curve is substantially proportional to the number of trapped electric charges. Where the electric charge is trapped in only the portions of the crystal grains, the amount of trapped electric charge is substantially proportional to the volume of the crystal grains. It follows that, if the total volume of the crystals, a part of the peripheral portion of which is away from the interface of the insulating film by a distance less than 0.7 nm, is halved, the hysteresis is also halved, with the result that an improvement of the MOSFET or the like can be expected.

It is not absolutely necessary for the nano-crystals to extend across the insulating film. As shown in FIGS. 13B and 13C referred to previously, it is possible for a thin SiO₂ film to be formed between the edge portion of the nano-crystal and the surface of the mixed film. Even in this case, if the thickness of the SiO₂ film is not larger than 0.7 nm, the distance from the interface of the mixed film is not larger than 0.7 nm in most of the microcrystals because the grain diameter of the nano-crystal is sufficiently large. It follows that the inconvenience of the trapped electric charge is not generated.

In the next step, a patterned gate electrode 134 and a patterned highly dielectric insulating film 133 are obtained as shown in FIG. 15C. The gate electrode 134 and the highly dielectric insulating film 133 can be formed, for example, as follows. In the first step, a gate electrode containing, for example, a SiGe layer 134 is deposited in a thickness of 100 nm within a mixed gas containing SiH₄ and GeH₄. Then, a resist pattern is formed by lithography, and an acidic ion etching is applied under an atmosphere of CF₄ and O₂ with the resultant resist pattern used as a mask so as to process the SiGe film 134 into the shape of the gate electrode. After the acidic ion etching step, the highly dielectric insulating film 133 including nano-crystals is processed with a solution containing HF.

In the next step, arsenic ions are implanted into the p-type silicon substrate 130 at a dose of 1×10¹⁴ cm⁻² under an accelerating energy of 300 eV. In this ion implantation step, the patterned gate electrode 134 and the patterned highly dielectric insulating film 133 are used as a mask. Further, a SiN film is deposited on the entire surface, followed by applying RIE etching to the entire surface so as to form a gate side wall SiN film 135 in a thickness of 10 nm, as shown in FIG. 15D. Still further, arsenic ions are implanted again at a dose of 1×10¹⁵ cm⁻² and under an accelerating energy of 10 keV with the SiGe film 134 and the side wall SiN film 135 used as a mask. After the ion implantation step, RTA (rapid temperature annealing) is applied at 900° C. for 30 seconds so as to form source-drain regions 136a, 136b and add an n-type impurity to the SiGe film 134 forming a gate electrode.

In the next step, a CoSi₂ film 137 is deposited on the source region, the drain region and the gate electrode by the deposition of cobalt, heat treatment and etching. Finally, a SiO₂ film 138 forming an interlayer insulating film is deposited on the entire surface by using, for example, TEOS, followed by forming a wiring layer 139 of an Al/TiN/Ti structure or a Cu/TiN/Ti structure in a manner to fill the contact holes connected to the source-drain regions. In the subsequent process, the wiring step for the second layer et seq. is carried out so as to finish the manufacture of an LSI.

In the semiconductor device thus manufactured, the nano-crystals contained in the highly dielectric insulating film 133 forming the gate insulating film have a diameter of about 5 nm and, thus, substantially extend through the upper and lower surfaces of the insulating film 133. It follows that the trapping energy level as shown in FIG. 12 referred to previously is not generated, making it possible to suppress the nonuniformity in the threshold value and the driving force. As a result, the characteristics of the MOS transistor, etc. can be improved.

In this Example 5, nano-crystals in the highly dielectric insulating film 133 are formed immediately after depositing the mixed film. However, it is possible to form the nano-crystals after depositing the gate electrode or after patterning the highly dielectric insulating film. Alternatively it is also possible to form the nano-crystals during activating the impurity doped in the semiconductor substrate.

### EXAMPLE 6

Example 6 is directed to an improvement of the annealing method of the mixed film in Example 5 described above.

Specifically, a TiO₂/SiO₂ mixed film 132 was deposited by the method similar to that employed in Example 5 under temperatures at which crystallization did not take place, e.g., under room temperature. Then, a heat treatment was applied at 600° C. for 30 seconds under a high pressure of 10 MPa so as to form a highly dielectric insulating film containing nano-crystals. It was possible to form nano-crystals having a grain diameter of about 5 nm in this case, too, as in Example 5. Further, the steps shown in FIGS. 15C to 15E were performed as in Example 5 so as to finish the manufacture of an LSI.

According to Example 6, it is possible to form nano-crystals having a diameter of about 5 nm in the mixed film 132 such that the nano-crystals extend across the insulating film, making it possible to obtain the effects similar to those obtained in Example 5. In addition, Example 6 produces an effect that, since the heat treatment is carried out under a high pressure, it is possible to carry out the annealing for preparation of the nano-crystals under a lower temperature. According to the experiment conducted by the present inventors, it is possible to form the nano-crystals required in Example 6 of the present invention by the heat treatment carried out under temperatures falling within a range of between 600° C. and 1,000° C. if the heat treatment is carried out under the pressure of 10 MPa.

### EXAMPLE 7

Example 7 is directed to an improvement in the method of forming the mixed film employed in Example 5 described previously.

Specifically, a TiO₂/SiO₂ mixed film 132 was deposited by the method similar to that employed in Example 5 under temperatures at which crystallization did not take place, e.g., under room temperature. In Example 7, however, the mixed film 132 was deposited in a large thickness of 100 nm. Then, a heat treatment was applied at 800° C. for 30 seconds under an Ar gas atmosphere so as to convert the mixed film into a highly dielectric insulating film containing TiO₂ nano-crystals. It was possible to form nano-crystals such that a majority of the formed nano-crystals had a grain diameter of about 5 nm in this case, too, as in Example 5.

Then, the thickness of the highly dielectric insulating film 133 was decreased to 5 nm by the treatment with a solution containing HF, e.g., a mixed solution containing 1 part of a 47% HF and 10 parts of H₂O, for 5 minutes. The etch back step of the highly dielectric insulating film can also be applied to the case other than the case where the etch back is performed uniformly over the entire surface. It is possible to apply the etch back to only a part, e.g., to only the p-channel MOS, to only the portion where the threshold voltage is partially changed, to only the portion corresponding to the logic SLI in a mixed LSI, or to only the portion corresponding to the memory LSI. Further, the steps shown in FIGS. 15C to 15E were performed as in Example 5 so as to finish the manufacture of an LSI. In this Example 7, it is also possible to decrease the thickness of the highly dielectric insulating film before heat treatment for forming nano-crystals.

According to Example 7, it is possible to form nano-crystals having a diameter of about 5 nm in the mixed film 132 such that the nano-crystals extend across the insulating film, making it possible to obtain the effects similar to those obtained in Example 6.

### EXAMPLE 8

In Example 8, an oxynitride film (not shown) having a thickness of 0.7 μm is formed on the silicon substrate 130 by the heat treatment at 850° C. for 5 seconds using a NO gas before formation of the mixed film that is to be converted into the gate insulating film. Then, as in Example 5, a TiO₂/SiO₂ mixed film 132 is formed in a thickness of 5 nm on the oxynitride film. Further, the steps shown in FIGS. 15C to 15E are performed as in Example 5 so as to finish the manufacture of an LSI.

According to Example 8, it is possible to form nano-crystals having a diameter of about 5 nm in the mixed film 132 such that the nano-crystals extend across the insulating film, making it possible to obtain the effects similar to those obtained in Example 5. Also, in Example 8, an oxynitride film is formed on the silicon substrate 130 before formation of the TiO₂/SiO₂ mixed film 132, with the result that, even if the mixed film 132 is formed and annealed under an oxygen-containing atmosphere, it is possible to suppress the diffusion of oxygen into the substrate.

### EXAMPLE 9

The present invention is not limited to each of the Examples described above. These Examples can be employed singly or in combination. It is also possible combine the Examples described above with the method described below.

Specifically, the mixed film can be formed as follows. In the first step, a Ti layer is formed on a clean silicon substrate by, for example, a sputtering method, a vapor deposition method, a CVD method or a plasma CVD method, followed by annealing the substrate under an inert atmosphere so as to form a titanium silicide layer on the substrate. Then, it is possible to peel of the unreacted Ti. Further, an annealing treatment is applied under an oxygen-containing atmosphere. It is possible for the oxygen-containing atmosphere to contain H₂O, and O₃ as well as O, N and OH in the state of plasma. Since Ti is readily oxidized, it is possible to apply the annealing treatment under the air atmosphere or under an atmosphere containing at most 10 kPa of the oxygen partial pressure at 100° C. or less. Then, an additional annealing treatment is applied at 800° C. under an Ar gas atmosphere so as to precipitate nano-crystals.

Further, it is possible to form a Ti layer under an oxygen-containing atmosphere so as to oxidize Ti at least partially. It is also possible to form a Ti layer on a silicon oxide film, followed by applying an annealing treatment so as to oxidize Ti at least partially. Further, an oxidation is performed, as required, followed by performing an annealing treatment so as to precipitate nano-crystals.

It is possible to form a mixed film containing a suitable combination of Ti, Si, a compound between Ti and Si and an oxide of at least one of these materials by a simultaneous sputtering method or a vapor deposition. It is not absolutely necessary to form the mixed film by a single deposition. It is also possible to form the mixed film by depositing several times a film having the same or different mixing ratio under the same or different atmospheres. Then, the oxidation is performed as required, followed by performing the annealing treatment so as to precipitate nano-crystals.

In each of the Examples described above, TiO₂ nano-crystals were formed in the insulating film. However, the nano-crystals formed in the insulating film are not limited to TiO₂ nano-crystals. A similar method can be applied even in the case where an amorphous layer having an energy level lower than the surrounding energy level is precipitated.

In each of the Examples described above, TiO₂ is contained as one of the components of the mixed film forming the insulating film. Alternatively, it is also possible to use an oxide, a nitride or an oxynitride of Ta, Y, Al, Zr, La, Hf, Nb or lanthanum series element such as La, Ce, Pr, Nd, Pm, Sm, Eu, Gd, Tb, Dy, Ho, Er, Tm, Yb and Lu in place of TiO₂. It should be noted, however, that the temperature at which nano-crystals are formed depends on the material. As the substrate for forming the insulating film of the present invention, it is required to use a surface not having a crystallinity. Alternatively, it is important to use the surface formed of a material having a large lattice mismatch with the metal oxide thereof. Otherwise, the crystal growth occurs preferentially from the substrate, resulting in failure to form nano-crystals. Of course, where Si(100) has a large lattice mismatch with the metal oxide thereof, it is possible to form the mixed film directly without worrying about the crystal growth.

The other component of the mixed film is not limited to SiO₂. It is also possible to use SiON or SiN in place of SiO₂. It should be noted, however, in the combination forming a conductive material such as TiN, it is naturally impossible to use SiN in combination with the other component such as TiN, though it is possible to use SiON in combination with, for example, TiN.

It is possible to use a material having a low resistivity such as Ag for forming the wiring. Further, it is possible to use, for example, TiSiN, WSiN or TaSiN for forming the underlying layer. It is also possible to bury W, NiSi, Al or Cu in the contact hole.

Further, a CoSi film is formed by a salicide process on the SiGe film used as the gate electrode. Alternatively, it is possible to deposit, for example, WSi₂ on the entire surface immediately after deposition of the SiGe film. It is possible to lower the resistivity of the gate by processing, for example, the WSi₂ film deposited on the entire surface. Also, the TiSiO film is deposited by a single depositing operation. However, it is of course possible to carry out the depositing operation several times by changing the mixing ratio.

In each of the Examples described above, SiGe was used as the material of the gate electrode. Alternatively, it is also possible to use polysilicon, a metal or a combination of a metal and a metallic silicon side gate material for forming the gate electrode.

In each of the Examples described above, the extension of the source-drain regions, i.e., the shallow junction portion below the SiN side wall, is formed by ion implantation alone. However, it is also possible to form a silicon layer on the substrate in a thickness of about 20 nm by a selective CVD method on the source-drain regions by using, for example, SiH₄, followed by applying an ion implantation. In this case, the accelerating energy in the ion implantation step can be increased to, for example, 10 keV so as to improve the ion implantation efficiency.

Each of the Examples described above is directed to a MOS transistor. However, it is possible to apply the technical idea of the present invention to various semiconductor devices using a highly dielectric insulating film including, for example, a MOS capacitor. Further, as already described in conjunction with Example 1, the technical idea of the present invention can be applied to a MOSFET of SOI structure and to a vertical MOS devices. Further, various modifications are available within the technical scope of the present invention.

As described above in detail, the present invention provides a semiconductor device, which permits suppressing the leakage current derived from the grain boundary, permits suppressing the nonuniformity in the threshold value and the driving force, and further permits improving the characteristics of the MOS transistor, etc. and a method of manufacturing the particular semiconductor device.

The present invention also provides a semiconductor device, which permits suppressing the leakage current derived from the crystal grain boundary, permits eliminating the trap of the charge within the film so as to suppress the nonuniformity in the threshold value and the driving force, and is effective at improving the characteristics of a MOS transistor, etc., and a method of manufacturing the particular semiconductor device.

To reiterate, the present invention can be highly effectively applied to a semiconductor device using a highly dielectric thin film and, thus, is prominently valuable in industry.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate, and
a circuit element using an insulating film formed on said semiconductor substrate,
said insulating film containing a silicon compound containing at least one element selected from the group consisting of an oxygen and a nitrogen, and a metal compound containing a metal other than silicon and at least one element selected from the group consisting of an oxygen and a nitrogen, nano-crystals being formed in said insulating film, the size of said nano-crystal being small enough to permit observation of a polycrystalline ring as a diffraction image when an electron beam having a beam diameter of the nanometer order is incident in parallel to said insulating film surface.

2. The semiconductor device according to claim 1, wherein said a silicon compound is a compound selected from the group consisting of a silicon oxide, a silicon nitride, and a silicon oxynitride.

3. The semiconductor device according to claim 1, wherein said nano-crystal grains are made of said metal compound.

4. The semiconductor device according to claim 2, wherein said nano-crystal grains are made of an oxide, a nitride or an oxynitride of a metal other than silicon.

5. The semiconductor device according to claim 1, wherein said nano-crystals grains has a diameter falling within a range of between 1 nm and 10 nm.

6. The semiconductor device according to claim 1, wherein said insulating film has a thickness falling within a range of between 3 nm and 20 nm.

7. The semiconductor device according to claim 1, wherein an oxynitride film is formed between said semiconductor substrate and said insulating film.

8. The semiconductor device according to claim 1, wherein said metals other than silicon is at least one metal selected from the group consisting of Ti, Ta, Y, Al, Zr, La, Hf, Nb and elements of lanthanum series.

9. The semiconductor device according to claim 1, wherein said functional element is a MOSFET, and said insulating film is a gate insulating film of said MOSFET.

10. The semiconductor device according to claim 1, wherein said nano-crystals being formed in said insulating film, the size of the largest nano-crystal grain in said insulating film being not larger than the thickness of said insulating film.

11. The semiconductor device according to claim 10, wherein the size in the thickness direction of said insulating film of the largest nano-crystal grain formed in said insulating film is substantially equal to the thickness of said insulating film.

12. The semiconductor device according to claim 1, wherein a part of the periphery of at least one of said nano-crystals being positioned within a distance of 0.7 nm from the interface of said insulating film.

13. The semiconductor device according to claim 1, wherein said insulating film is a mixed film containing said silicon compound and said metal compound.

14. A method of manufacturing a semiconductor device according to claim 1, comprising:
forming an insulating film containing a silicon compound containing at least one element selected from the group consisting of an oxygen and a nitrogen, and a metal compound containing a metal other than silicon and at least one element selected from the group consisting of an oxygen and a nitrogen, on a semiconductor substrate under temperatures at which crystallization does not take place; and
applying a heat treatment to precipitate a nano-crystalline metal oxide within said mixed film.

15. A method of manufacturing a semiconductor device, comprising:
forming insulating film being a mixed film including a silicon compound containing at least one element selected from the group consisting of an oxygen and a nitrogen, and a metal compound containing a metal other than silicon and at least one element selected from the group consisting of an oxygen and a nitrogen on a semiconductor substrate under temperatures at which crystallization does not take place; and
applying a heat treatment to precipitate a nano-crystalline metal oxide within said mixed film.
